(19) United States
(12) Patent Application Publication
(10) Pub. No.: US 2010/0081283 A1
(43) Pub. Date: Apr. 1, 2010

(54) METHOD FOR MANUFACTURING SEMICONDUCTOR DEVICE

(76) Inventor: Koji HASHIMOTO, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/549,691

(22) Filed: Aug. 28, 2009

(30) Foreign Application Priority Data
Sep. 30, 2008 (JP) P2008-255635

(51) Int. Cl. H01L 21/311

(52) U.S. Cl. 438/703; 257/E21.214; 257/E21.294

(57) ABSTRACT

According to an aspect of the present invention, there is provided a method for manufacturing a semiconductor device, the method including: sequentially forming a first film and a second film on a base film; processing the second film, thereby forming a second pattern; processing the first film with the second pattern as a mask, thereby forming a first pattern; removing the second pattern; depositing a third film on the base film and on the first pattern; processing the third film, thereby forming a third side wall pattern on a side wall of the first pattern; removing the first pattern; and processing the base film with the third side wall pattern as a mask, thereby forming a target pattern so that, in the target pattern, a space dimension is larger than a pattern dimension.

### CROSS-REFERENCE TO RELATED APPLICATIONS

This application claims priority from Japanese Patent Application No. 2008-255635 filed on Sep. 30, 2008, the entire contents of which are incorporated herein by reference.

### BACKGROUND OF THE INVENTION

1. Field of the Invention

An aspect of the present invention relates to a method for manufacturing a semiconductor device, and a method for forming a pattern.

2. Description of the Related Art

In recent years, as one of the technologies for realizing the finer wiring patterns in the semiconductor integrated circuits, there is known a pattern forming method for forming a wiring pattern and a gate electrode by forming a core pattern on a processed film, forming a side wall pattern on the side wall of the core pattern formed, and processing the processed film with the side wall pattern or pattern embedded between the side wall patterns as the mask (e.g., refer to U.S. Pat. No. 6,063,688-B).

However, in this pattern forming method, there are different processes having important factors on the pattern dimension and the space dimension of the pattern formed on the processed film, whereby the percentage or probability of causing a dimensional dispersion in the region is varied. Accordingly, the pattern dimension in the gate pattern is dispersed, possibly degrading the reliability of the semiconductor device.

### SUMMARY OF THE INVENTION

According to an aspect of the present invention, there is provided a method for manufacturing a semiconductor device, the method including: sequentially forming a first film and a second film on abase film; processing the second film, thereby forming a second pattern; processing the first film with the second pattern as a mask, thereby forming a first pattern; removing the second pattern; depositing a third film on the base film and on the first pattern; processing the third film, thereby forming a third side wall pattern on a side wall of the first pattern; removing the first pattern; and processing the base film with the third side wall pattern as a mask, thereby forming a target pattern so that, in the target pattern, a space dimension is larger than a pattern dimension.

According to another aspect of the present invention, there is provided a method for manufacturing a semiconductor device, the method including: sequentially forming a first film and a second film on a base film; processing the second film, thereby forming a second pattern; processing the first film with the second pattern as a mask, thereby forming a first pattern; removing the second pattern; depositing a third film on the base film and on the first pattern; processing the third film, thereby forming a third side wall pattern on a side wall of the first pattern; embedding a fourth pattern between the side wall patterns on the base film; removing the third side wall pattern; and processing the base film with the first and fourth patterns as a mask, thereby forming a target pattern so that, in the target pattern, a space dimension is smaller than a pattern dimension.

### BRIEF DESCRIPTION OF THE DRAWINGS

FIGS. 1A to 1H illustrate a semiconductor device manufacturing method according to an embodiment 1 of the invention.

FIG. 2 is a cross-sectional view illustrating a pattern formed by the related-art semiconductor device manufacturing method.

FIGS. 3A to 3F illustrate a semiconductor device manufacturing method according to an embodiment 2 of the invention.

FIG. 4 is a cross-sectional view illustrating a pattern formed by another related-art semiconductor device manufacturing method.

### DETAILED DESCRIPTION OF THE INVENTION

Embodiments of the present invention will be described below with reference to the drawings.

### Embodiment 1

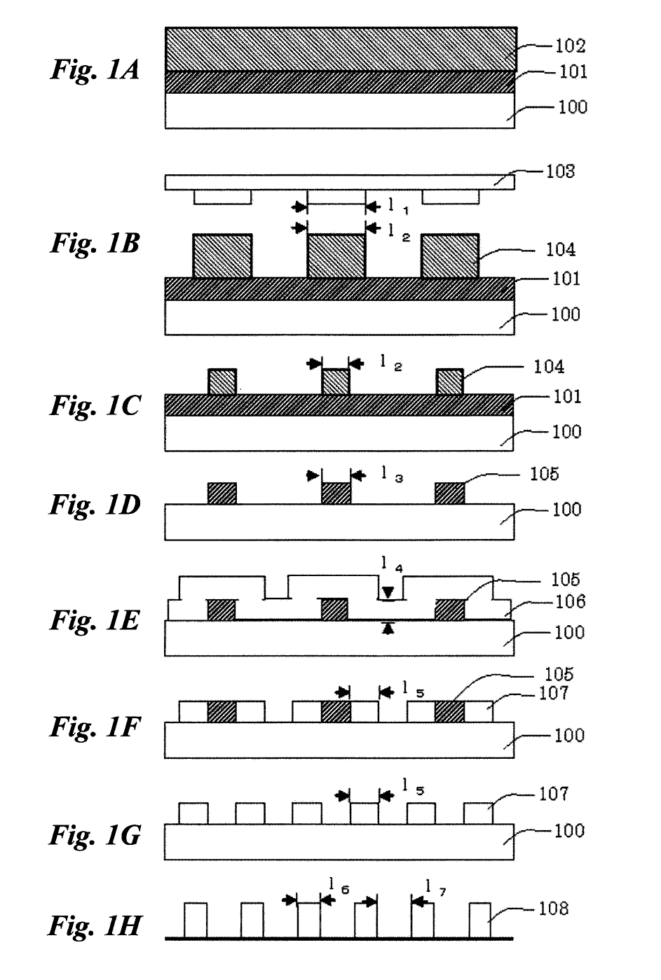

Referring to FIGS. 1A to 1H, a semiconductor device manufacturing method according to the embodiment 1 will be described below. FIGS. 1A to 1H illustrate the semiconductor device manufacturing method.

As shown in FIG. 1A, a gate oxide film (not shown) such as a silicone oxide film, abase film 100 such as a polycrystalline silicon film and a first film 101 such as a silicone nitride film are sequentially formed on a semiconductor substrate (not shown) made of single crystal silicon. The base film 100 is to be formed into a gate pattern. Further, a second film (resist film, e.g.) 102, is coated and formed on the first film 101, using a CVD (Chemical Vapor Deposition) method. The first film 101 may be composed of plural material layers.

Next, a mask pattern formed on an exposure mask 103 is transferred to the resist film 102 by photo-lithography, and a resist pattern 104 (second pattern 104) is formed on the first film 101 by processing (developing) the resist film, as shown in FIG. 1B. Before performing the above process, the mask pattern dimension l₁ of the exposure mask 103, such as the minor axis dimension (width) of pattern in a line-like pattern, is measured beforehand, and the process conditions in the photo-lithography, such as exposure amount and focus value, are decided based on the measurement mask pattern dimension l₁.

For example, when the mask pattern dimension l₁ is greater than a desired set value, the exposure amount in the following photo-lithography step is made smaller than in the set conditions, or when the mask pattern dimension l₁ is smaller than the desired set value, the exposure amount in the following photo-lithography step is made greater than in the set conditions, whereby the process conditions are adjusted to form the resist pattern 104 of desired dimension. Therefore, even if the measured mask pattern dimension l₁ of the exposure mask 103 is different from the desired design dimension, the resist pattern 104 can be made closer to the desired design dimension by appropriately adjusting the exposure amount based on the error.

Also, the dimension l₂ of the resist pattern 104 formed by photo-lithography, such as the minor axis dimension (width) of pattern or pitch in a line-like pattern, may be measured, and checked if it accords with the design dimension. For example, in the semiconductor device manufacturing method according to this embodiment, the pattern pitch of the resist pattern 104 is about twice the pitch of the final gate pattern. For example, when forming the gate pattern having a gate width of 45 nm, the pitch of the gate pattern is 90 nm, and the pattern pitch of the resist pattern 104 is about 180 nm.

Next, the resist pattern 104 is slimmed by etching, as shown in FIG. 1C. As the etching, for example, a CDE (Chemical Dry Etching) method, a wet method, and a width-direction RIE (Reactive Ion Etching) for an anti-reflection film (not shown) on the resist film 102 are used. The etching conditions are determined based on, for example, the slimming amount, the type/concentration/pressure of etching gas, the type/concentration of etchant, the resist material, the anti-reflection film material and the film material of under-layer.

The etching conditions (process conditions) in slimming, such as type of the etching gas, etching gas pressure, discharge power in etching, slimming amount by etching and etching rate, are decided based on a difference between the pre-measured resist pattern dimension l₂ and the design dimension. For example, when the resist pattern dimension l₂ is greater than the desired set value, the slimming amount is increased over the normal value, or when the resist pattern dimension l₂ is formed smaller than the set value, the slimming amount is decreased below the normal value, whereby the process conditions are appropriately adjusted. In this way, even if the measured resist pattern dimension l₂ is different from the desired design pattern dimension, the resist pattern 104 can be made closer to the desired design pattern dimension by appropriately adjusting the process conditions in slimming based on the error.

At this time, the resist pattern dimension l₂ after slimming is measured. With the semiconductor device manufacturing method according to this embodiment, the pattern width l₂ of the slimmed resist pattern 104 is almost equivalent to the space width of the final gate pattern. For example, when forming the periodic gate pattern with a space of 30 nm, the dimension of the slimmed resist pattern 104 is also 30 nm.

Next, the first film 101 is etched by RIE with the slimmed resist pattern 104 as the mask, and a first pattern 105 is formed on the base film 100, as shown in FIG. 1D. The process conditions for this etching process, such as the etching amount, type of the etching gas, etching gas pressure, discharge power in etching and etching rate, are decided based on at least one of the resist pattern dimensions l₂ before and after sliming. For example, when the resist pattern dimension l₂ is greater than the desired dimension, the etching time is made longer than in the set conditions, or when the resist pattern dimension l₂ is smaller than the desired dimension, the etching time is made shorter than in the set conditions, whereby the process conditions are appropriately adjusted. In this way, even if the measured dimensions l₂ of the resist pattern 104 before and after slimming are different from the desired design pattern dimensions, the first pattern dimension l₃ can be made closer to the desired design pattern dimension by appropriately adjusting the process conditions based on their errors.

Though the resist pattern 104 is slimmed in this embodiment, the first pattern 105 may be slimmed, as needed, after the first pattern 105 is formed. If a silicone nitride film is employed as the first pattern 105, for example, the first pattern 105 can be slimmed by wet etching with hot phosphoric acid. For example, when the first pattern 105 is slimmed, the slimming conditions are adjusted so that the first pattern 105 becomes closer to the desired design dimension, and the dimension thereof is checked by measuring the dimension l₃ after slimming.

After processing the first film 101, the resist film 102 (resist pattern 104) is peeled through an ashing process (O₂ asher) in the oxygen atmosphere. The dimension is checked by measuring the first pattern dimension l₃ after peeling the resist film 102.

Next, a third film 106 is deposited on the first pattern 105 and the base film 100 by the CVD method, as shown in FIG. 1E. For the third film 106, an oxide film or nitride film having a selective etching ratio for the first film 101 and the base film 100 is employed.

The process conditions in depositing the third film 106, such as type of the raw material gas and the set deposited film thickness of the third film 106, are adjusted so that the third film 106 may have the desired film thickness. On the other hand, a difference from the desired set film thickness is checked by measuring the deposited film thickness l₄ of the deposited third film 106.

Next, the third film 106 is etched by RIE to remove the third film 106 formed on the first pattern 105 and the base film 100, and a third side wall pattern 107 is formed by leaving the third film 106 only on the side wall of the first pattern 105, as shown in FIG. 1F.

The process conditions in etching the third film 106, such as the etching time, type of the etching gas, etching gas pressure and discharge power in etching, are decided based on the deposited film thickness l₄ of the third film 106 measured beforehand. For example, when the deposited film thickness l₄ of the third film 106 is greater than the set film thickness, the etching time is made longer than the set time, or when the deposited film thickness l₄ of the third film 106 is thinner than the set film thickness, the etching time is made shorter than the set time, whereby the process conditions are appropriately adjusted. In this way, even if the deposited film thickness l₄ of the third film 106 is different from the desired design film thickness, the third side wall pattern dimension l₅ can be made closer to the desired design pattern dimension by appropriately adjusting the process conditions based on the error.

Next, the first pattern 105 is peeled by wet etching or the like, as shown in FIG. 1G.

Further, after peeling the first pattern 105, the dimension l₅ of the sidewall pattern 107, such as pattern width, pattern diameter or pattern area, is measured. In this embodiment, the dimension l₅ of the side wall pattern 107 is finally almost equivalent to the gate length of the gate pattern.

Next, the base film 100 is etched by RIE with the third side wall pattern 107 as the mask to form a gate pattern 108 on the base film 100, as shown in FIG. 1H. Subsequently, the side wall pattern 107 is peeled.

The process conditions in etching the base film 100, such as the etching time, type of the etching gas, etching gas pressure, discharge power in etching and etching rate, are decided based on at least one information of the deposited film thickness l₄ of the third film 106 measured beforehand and the third side wall pattern dimension l₅. For example, when the deposited film thickness l₄ of the third film 106 is greater than the set film thickness, the etching time is made longer than in the set conditions, or when the deposited film thickness l₄ of the third film 106 is smaller than the set film thickness, the etching time is made shorter than in the set conditions. Similarly, when the third side wall pattern dimension is greater than the set dimension, the etching time is made longer than in the set conditions, or when the third side wall pattern dimension l₅ is smaller than the set dimension, the etching time is made shorter than in the set conditions, whereby the process conditions are appropriately adjusted.

In this way, even if the deposited film thickness l₄ of the third film 106 or the side wall pattern dimension l₅ is different from the desired value, the dimension l₆ of the gate pattern 108 can be made closer to the desired design dimension by the process conditions based on the error.

The pattern formation of the semiconductor device manufacturing method according to this embodiment has been described above.

With the gate pattern forming method, in which the base film 100 is processed with the third side wall pattern 107 formed on the side wall of the first pattern 105 as the mask, the gate pattern 108 is formed with the side wall pattern 107 as the mask. Therefore, the dimension of the gate pattern 108 depends mainly on the third side wall pattern dimension l₅. On the other hand, the space dimension between the gate patterns 108 depends mainly on the dimension of the resist pattern 104, the space dimension of the resist pattern 104, the pattern dimension of the first pattern 105 and the space dimension of the first pattern 105. Accordingly, the major causes of dispersion of the gate pattern dimension from the design dimension may be the dispersions of the film thickness l₄ in depositing the third film 106 and the side wall pattern dimensions l₅ in performing RIE for the third film 106 and in peeling the first pattern 105 between the side wall patterns from the respective desired design values, in addition to the dispersion occurring in processing the base film 100, as shown in FIGS. 1E to 1H. On the other hand, the major causes of dispersion of the gate pattern space dimension from the design dimension may be the dispersions of the film thickness l₄ in depositing the third film 106 and the side wall pattern dimensions l₅ in performing RIE for the third film 106 and in peeling the first pattern 105 between the side wall patterns from the respective desired design values, and the dispersion occurring in processing the base film 100, as well as the dispersions of the mask pattern dimension l₁ of the exposure mask 103, the resist pattern dimensions l₂ before and after slimming, and the first pattern dimension l₃ in processing the first film 101 with the resist pattern 104 as the mask from the respective desired design values.

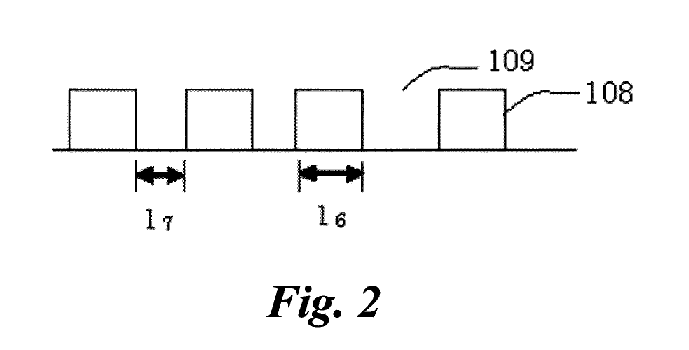

FIG. 2 is a cross-sectional view of the gate pattern formed with such side wall pattern as the mask by the related-art semiconductor device manufacturing method. With the related-art semiconductor device manufacturing method, as shown in FIG. 2, since the cause of dispersing the dimension l₆ of the gate pattern 108 is more significant than the cause of dispersing the dimension l₇ of the gate pattern space 109, the gate pattern space dimension l₇ is highly apt to be more dispersive from the desired design dimension than the gate pattern dimension l₆.

On the contrary, with the semiconductor device manufacturing method according to this embodiment, information such as pattern dimension is obtained at each step of the manufacturing process as shown in FIGS. 1A to 1H, and the final gate pattern 108 is formed while deciding the following process conditions based on those information. Therefore, in the manufacturing process for forming the fine pattern of the semiconductor device, the dimension control can be performed by modifying the resist pattern dimension l₂ or the like to the desired design value, whereby the pattern of highly precise dimension extremely closer to the desired design value can be finally formed.

Also, in this embodiment, since the dispersion in the gate pattern space dimension l₇ is apt to be greater than the dispersion in the gate pattern dimension l₆, the design dimension of the gate pattern (target dimension of gate pattern) can be designed to be smaller than the design dimension of the gate pattern space (target dimension of the gate pattern space) to improve a process margin. By adapting such design pattern with the gate pattern forming method according to this embodiment, the desired device performance of the semiconductor device can be secured. Also, degradation of a device performance can be suppressed by making the gate pattern space dimension larger than the gate pattern dimension, in accordance with probability of causing the dimensional dispersion, as shown in FIG. 1H.

In this embodiment, after the first film 101 is peeled in the process as shown in FIG. 1G, the side wall pattern dimension l₅ may be adjusted by measuring the dimension l₅ of the third side wall pattern 107, and further slimming the third side wall pattern 107.

The process conditions in slimming the side wall pattern 107, such as the etching time, type of the etching gas, etching gas pressure, discharge power, slimming amount and etching rate, are decided based on at least one of the deposited film thickness l₄ of the third film 106 and the dimension l₅ of the third side wall pattern 107. For example, when the side wall pattern dimension l₅ is greater than the desired design value, the slimming amount is increased over the set conditions, or when the side wall pattern dimension l₅ is smaller than the desired design value, the slimming amount is decreased below the set conditions, whereby the process conditions are appropriately adjusted. In this way, even if the side wall pattern 107 is different from the desired design pattern dimension, the resist pattern 104 can be made closer to the desired design pattern dimension by appropriately adjusting the slimming conditions based on the error.

Also, the side wall pattern dimension is measured after slimming, and the etching conditions in the etching process for the base film 100 are decided based on the dimension, as shown in FIG. 1H.

In this way, by adjusting the side wall pattern dimension by slimming, and by further adjusting the etching conditions, the dimension of the gate pattern 108 that is formed by etching the base film 100 with the side wall pattern 107 as the mask can be made at higher precision.

### Embodiment 2

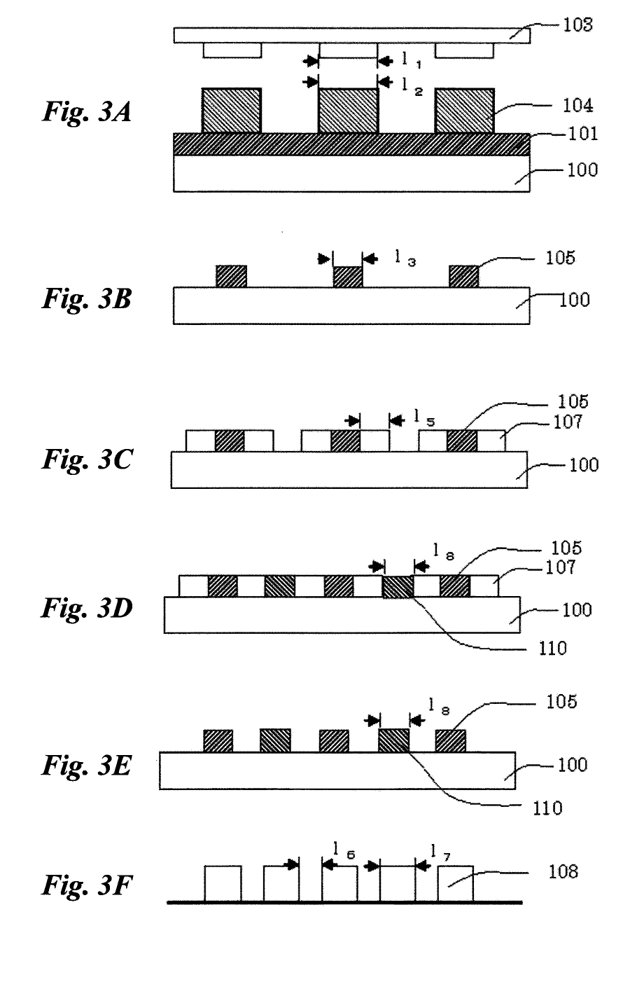

Referring to FIGS. 3A to 3F, a semiconductor device manufacturing method according to the embodiment 2 will be described below. FIGS. 3A to 3F illustrate the semiconductor device manufacturing method.

The semiconductor device manufacturing method according to this embodiment is different from the semiconductor device manufacturing method according to the embodiment 1, in that the base film is processed with the first pattern as the mask. In the following explanation of this embodiment, the same parts are designated by the same reference numerals as in the above-described embodiment 1, and the detailed explanation thereof is omitted.

That is, after the base film 100, the first film 101 and the second film (resist film) 102 are formed sequentially on the semiconductor substrate, the pattern is transferred to the resist film 102 by photo-lithography using the exposure mask 103 having a mask pattern, and the second pattern (resist pattern) 104 is formed on the first film 101, as shown in FIG. 3A.

The mask pattern dimension 11 of the exposure mask 103 is measured before performing the photo-lithography, and the process conditions in the photo-lithography, such as the exposure amount, are decided based on the measurement result of the mask pattern dimension l₁. Further, the dimension l₂ of the resist pattern 104 formed by photo-lithography is measured.

Next, the resist pattern 104 is slimmed by etching with the CDE method, and the first film 101 is etched by RIE with the slimmed resist pattern 104 as the mask to form the first pattern 105 on the base film 100, as shown in FIG. 3B.

The process conditions in slimming, such as the slimming amount, are decided based on the resist pattern dimension l₂ measured beforehand. At this time, the resist pattern dimension l₂ after slimming is measured. Also, the process conditions in etching, such as the over-etching time, are decided based on at least one information of the resist pattern dimensions l₂ before and after slimming measured beforehand. Further, after peeling the resist film 102, the first pattern dimension l₃ is measured.

Though the resist pattern 104 is slimmed in this embodiment, the first pattern 105 may be appropriately slimmed after the first pattern 105 is formed.

Next, the third side wall pattern 107 is formed on the side wall of the first pattern 105 by depositing the third film 106 by the CVD method and etching the third film 106 by RIE, as shown in FIG. 3C.

The process conditions in depositing the third film 106, such as the deposited film thickness, are decided based on at least one dimensional information of the resist pattern dimensions l₂ before and after slimming and the first pattern dimension l₃. Further, after depositing the third film 106, the film thickness l₄ is measured.

Also, the process conditions in etching the third film 106, such as the over-etching time, are decided based on the measured deposited film thickness l₄ of the third film 106. After etching the third film 106, the dimension l₅ of the third side wall pattern 107 is measured.

Next, in this embodiment, a fourth film such as a nitride film is deposited on the base film 100 using the CVD method so as to be embedded between the third side wall patterns 107. And, the fourth film on the side wall pattern 107 and the first pattern 105 is polished and removed by a CMP (Chemical Mechanical Polishing) method to form a fourth pattern 110, as shown in FIG. 3D.

Next, the third side wall pattern 107 is peeled by isotropic etching such as the CDE method or wet etching method, and the first and fourth patterns 110 are formed on the base film 100, as shown in FIG. 3E. Also, after peeling the side wall pattern 107, the first and fourth pattern dimensions l₃ and l₈ are measured.

Subsequently, the base film 100 is etched by RIE with the first and fourth patterns 105 and 110 as the mask, and the first and fourth patterns 105 and 110 are peeled to form the gate pattern 108, as shown in FIG. 3F.

The process conditions in etching this base film 100, such as the over-etching time, are decided based on the film thickness l₄ of the third film 106 measured beforehand, the dimension l₅ of the third side wall pattern 107, and the dimensions l₃ and l₈ of the first and fourth patterns 110. For example, when the film thickness l₄ of the third film 106 or the side wall pattern dimension l₅ is greater than the desired design value, the over-etching time for the base film 100 is made shorter than normally because the fourth pattern dimension l₈ is smaller than the desired design dimension, or when the film thickness l₄ of the third film 106 or the third side wall pattern dimension l₅ is smaller than the desired design value, the over-etching time is made longer than normally because the fourth pattern dimension l₈ is greater than the desired design dimension. Similarly, when the dimensions of the first and fourth patterns 105 and 110 are smaller than the desired design values, the over-etching time for the base film 100 is made shorter than normally, while when the first and fourth pattern dimensions l₃ and l₈ are greater than the desired design values, the over-etching time for the base film 100 is made longer than normally, whereby the process conditions are adjusted.

The method for forming the fine gate pattern 108 of the semiconductor device with the semiconductor device manufacturing method according to this embodiment has been described above.

With the semiconductor device manufacturing method, in which the base film 100 is processed with two patterns of the first pattern 105 formed on the base film 100 and the fourth pattern 110 formed between the side wall patterns 107 formed on the side wall of the first pattern 105 as the mask, the space dimension of the gate pattern 108 depends on the dimension of the side wall pattern 107. On the other hand, the pattern dimension of the gate pattern 108 depends on the dimensions of the first pattern 105 and the fourth pattern 110. Therefore, the space dimension of the gate pattern 108 depends mainly on the side wall pattern dimension l₅, while the pattern dimension of the gate pattern 108 depends mainly on the dimensions of the resist pattern 104, the first and fourth patterns 105 and 110, the resist pattern space, and the first pattern space. That is, the major causes of dispersion of the space dimension from the desired design dimension may be the dispersions of the deposited film thickness l₄ in depositing the third film 106 and the side wall pattern dimension l₅ in etching the side wall pattern 107 from the respective desired design values. On the other hand, the major causes of dispersion of the pattern dimension from the desired design dimension may be the dispersions of not only the deposited film thickness l₄ of the third film 106 and the side wall pattern dimension l₅, but also the mask pattern dimension l₁ of the exposure mask 103, the resist pattern dimension l₂ in transferring the mask pattern to the resist film 102, the resist pattern dimension l₂ after slimming, and the first pattern dimension l₃ in processing the first film 101 with the resist pattern 104 as the mask from the respective desired design values.

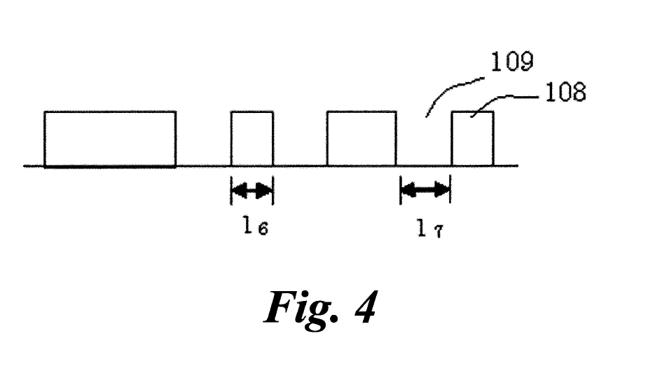

FIG. 4 is across-sectional view of the gate pattern formed by the related-art semiconductor device manufacturing method. Since the cause of dispersing the dimension of the gate pattern 108 is more significant than the cause of dispersing the gate pattern space dimension l₆, as shown in FIG. 4, the gate pattern dimension l₅ is more apt to be dispersive from the desired design dimension than the gate pattern space dimension l₇.

In this embodiment, information such as pattern dimension is obtained at a given step of the manufacturing process, and the following process conditions are appropriately decided based on those information, whereby in a given manufacturing process for forming the fine pattern of the semiconductor device, the resist pattern dimension l₂ can be appropriately modified to the desired design value to make the dimension control, and the highly precise pattern extremely closer to the desired design value can be finally formed.

In this embodiment, after the side wall pattern 107 is peeled at the step of the process as shown in FIG. 3E, the first and fourth pattern dimensions l₃ and l₈ may be adjusted by measuring the dimensions of the first and fourth patterns 105 and 110, and further slimming the first and fourth patterns 105 and 110 by the CDE method or wet method.

Herein, the process conditions in slimming the first and fourth patterns, such as the slimming amount, are decided based on the first and fourth pattern dimensions l₃ and l₈ measured beforehand. In this way, even if the measured first and fourth pattern dimensions l₃ and l₈ are different from the desired design pattern dimensions, the first and fourth patterns 105 and 110 can be made closer to the desired design pattern dimensions by appropriately adjusting the slimming conditions based on the error.

Also, the first and fourth pattern dimensions l₃ and l₈ are measured after slimming, and the etching conditions in the etching process for the base film 100 are decided based on the dimensions, as shown in FIG. 3F.

In this way, the dimension of the gate pattern 108 formed by etching the base film 100 with the first and fourth patterns 105 and 110 as the mask can be made at higher precision by adjusting the first and fourth pattern dimensions l₃ and l₈ by slimming and further adjusting the etching conditions.

Also, with the pattern forming method according to this embodiment, since the dispersion in the pattern dimension of the gate pattern 108 is apt to be greater than the dispersion in the space dimension, the gate pattern 108 having the high process margin and the desired device performance can be easily formed by designing the space dimension to be larger than the pattern dimension. A degradation of the device performance can be suppressed by making, in the gate pattern 108, the pattern dimension larger than the space dimension, in accordance with probability of causing the dimensional dispersion, as shown in FIG. 3F.

Though the method for forming the gate pattern 108 according to the embodiments 1 and 2 has been described above, it is possible to form not only the gate pattern 108 but also the fine hole or fine wiring pattern, particularly the line-like wiring pattern according to the invention.

Though the resist film 102 is employed as the second film 102 formed on the first film 101 in the embodiments 1 and 2, any other film than the resist film 102, such as an organic film having a selective etching ratio for the first film 101, may be employed for the second film 102. In such a case, the resist film may be further formed on the second film 102, and the second film 102 may be processed by photo-lithography and RIE to form the second pattern 104 on the first film 101.

According to an aspect of the present invention, there is provided a semiconductor device manufacturing method having the pattern of desired dimension with high reliability.

What is claimed is:

1. A method for manufacturing a semiconductor device, the method comprising:
sequentially forming a first film and a second film on a base film;
processing the second film, thereby forming a second pattern;
processing the first film with the second pattern as a mask, thereby forming a first pattern;
removing the second pattern;
depositing a third film on the base film and on the first pattern;
processing the third film, thereby forming a third side wall pattern on a side wall of the first pattern;
removing the first pattern; and
processing the base film with the third side wall pattern as a mask, thereby forming a target pattern so that, in the target pattern, a space dimension is larger than a pattern dimension.

2. The method according to claim 1, further comprising:
slimming the second pattern,
wherein the step of slimming the second pattern is performed before the step of forming the first pattern.

3. The method according to claim 2, further comprising:
measuring a pattern dimension of the second pattern.

4. The method according to claim 3,
wherein the step of measuring the pattern dimension is performed before the step of slimming the second pattern.

5. The method according to claim 4,
wherein the step of sliming the second pattern includes:
performing an etching process, and
wherein an etching condition in the etching process is determined based on the measured pattern dimension.

6. The method according to claim 5,
wherein, as the etching condition, at least one of an etching gas type, an etching gas pressure and a discharging power is changed based on the measured pattern dimension.

7. The method according to claim 3,
wherein the step of measuring the pattern dimension is performed after the step of slimming the second pattern.

8. The method according to claim 1, further comprising:
slimming the third side wall pattern;
wherein the step of slimming the third side wall pattern is performed before the step of forming the target pattern.

9. The method according to claim 1, further comprising:
generating a design pattern;
wherein the target pattern is formed in accordance with the design pattern.

10. The method according to claim 9,
wherein the design pattern is generated based on a probability of causing a dimension dispersion in a manufacturing process, and
wherein, in the design pattern, a space dimension is larger than a pattern dimension.

11. A method for manufacturing a semiconductor device, the method comprising:
sequentially forming a first film and a second film on a base film;
processing the second film, thereby forming a second pattern;
processing the first film with the second pattern as a mask, thereby forming a first pattern;
removing the second pattern;
depositing a third film on the base film and on the first pattern;
processing the third film, thereby forming a third side wall pattern on a side wall of the first pattern;
embedding a fourth pattern between the side wall patterns on the base film;
removing the third side wall pattern; and
processing the base film with the first and fourth patterns as a mask, thereby forming a target pattern so that, in the target pattern, a space dimension is smaller than a pattern dimension.

12. The method according to claim 11, further comprising:
slimming the second pattern,
wherein the step of slimming the second pattern is performed before the step of forming the first pattern.

13. The method according to claim 12, further comprising:
measuring a pattern dimension of the second pattern.

14. The method according to claim 13,
wherein the step of measuring the pattern dimension is performed before the step of slimming the second pattern.

15. The method according to claim 14,
wherein the step of sliming the second pattern includes:
performing an etching process, and
wherein an etching condition in the etching process is determined based on the measured pattern dimension.

16. The method according to claim 15,
wherein, as the etching condition, at least one of an etching gas type, an etching gas pressure and a discharging power is changed based on the measured pattern dimension.

17. The method according to claim 13,
wherein the step of measuring the pattern dimension is performed after the step of slimming the second pattern.

18. The method according to claim 11, further comprising:
slimming the first and fourth patterns;
wherein the step of slimming the first and fourth patterns is performed before the step of forming the target pattern.

19. The method according to claim 11, further comprising:
generating a design pattern;
wherein the target pattern is formed in accordance with the design pattern.

20. The method according to claim 19,
wherein the design pattern is generated based on a probability of causing a dimension dispersion in a manufacturing process, and
wherein, in the design pattern, a space dimension is smaller than a pattern dimension.
